(19) United States
(12) Patent Application Publication
(10) Pub. No.: US 2022/0219378 A1
(43) Pub. Date: Jul. 14, 2022

(54) IMPRINT APPARATUS, CONTROL METHOD, STORAGE MEDIUM, AND METHOD OF MANUFACTURING ARTICLE

(71) Applicant: CANON KABUSHIKI KAISHA, Tokyo (JP)

(72) Inventor: Takashi SHIBAYAMA, Tochigi (JP)

(21) Appl. No.: 17/568,194

(22) Filed: Jan. 4, 2022

(30) Foreign Application Priority Data
Jan. 13, 2021 (JP) 2021-003757

(51) Int. Cl. B29C 59/02; B29C 59/00

(52) U.S. Cl. CPC B29C 59/02; B29C 2037/903; B29C 59/002

(57) ABSTRACT

An imprint apparatus that forms a pattern of an imprint material on a substrate by using a mold comprising: at least one processor or circuit configured to function as a holding unit configured to hold the mold; an actuator configured to apply a force to a side surface of the mold held by the holding unit; wherein the holding unit includes a first mechanism that is able to hold the mold and is capable of limiting a motion of the mold in a direction in which the actuator applies the force; wherein the holding unit includes a second mechanism that is different from the first mechanism and that is able to hold the mold while allowing the motion of the mold in the direction in which the actuator applies the force.

### BACKGROUND OF THE INVENTION

### Field of the Invention

The present invention relates to an imprint apparatus and the like.

### Description of the Related Art

The demand for the miniaturization of semiconductor devices is increasing, and therefore, an imprint technique capable of forming a fine pattern (structure) on the order of several nanometers is attracting attention in addition to the conventional photolithography techniques. This imprint technique is a microfabricating technique in which an uncured imprint material is supplied (coated) onto a substrate, the imprint material and a mold are brought into contact with each other, and a pattern of the imprint material that corresponds to a fine, uneven pattern formed on the mold is thereby formed on the substrate.

In the imprint technique, photocuring is one of the methods for curing an imprinting material. The photocuring method is a method for forming a pattern of the imprint material on a substrate by irradiating the imprint material with light in a state in which the imprint material supplied to a shot region on the substrate is brought into contact with the mold, curing the imprinted material, and separating the mold from the cured imprinted material.

During aligning the pattern of the mold and the shot region on the substrate, a misalignment in shift and rotating directions is corrected by relatively moving the mold and the substrate based on the relative position of a mark formed on the mold and a mark formed on the substrate. Further, magnification errors and shape errors in skew, trapezoidal shape, arched shape, and bobbin winding are corrected by deforming the mold.

In order to improve the accuracy of the superposition of the pattern of the mold and the substrate, devices for deforming the mold with an accuracy of several nanometers or less are required. These devices include sensors and actuators for applying an external force to the mold to change the pattern into a predetermined shape and the actuators are arranged at a plurality of sides so as to surround the outer periphery of the mold.

For example, Japanese Patent Application Laid-Open No. 2009-141328 and Japanese Patent Application Laid-Open No. 2018-056533 propose an imprint apparatus having an actuator between a side surface of a mold and a support structure, and having a force sensor between the actuator and the support structure. In the imprint apparatus, a compression force applied from the actuator to the side surface of the mold is detected by a force sensor and feedback control is performed.

Some imprint apparatuses hold the upper surface of the mold by suction. From the viewpoint of a fail-safe mechanism, such an imprint apparatus is required to have a mechanism for reducing the probability that the mold will drop. Japanese Patent Application Laid-Open No. 2017-034088 discloses a dropping prevention mechanism that prevents the mold from dropping out in response to a stop or lack of supply of a holding force that holds the mold.

However, in imprint apparatuses, a misalignment of the mold occurs in the shift and rotation directions due to an external force applied to the mold in a mold pressing step in which the mold is brought into contact with the imprint material on the substrate and in a mold rereleasing step in which the mold is separated from the imprint material on the substrate. In such a case, in principle, it is impossible to return the mold to the original position by using the feedback control that uses the above force sensor.

The misalignment of the mold causes an unintended deformation (distortion) of the mold due to friction between the mold and a holding unit (chuck) that holds the mold and becomes a factor for lowering the accuracy in superposition. Additionally, the moving amounts of the mold and the substrate required for alignment between the mold and the substrate increase due to the increase in the relative misalignment between the mold and the substrate immediately after the mold pressing step, and as a result, the alignment time is affected.

Furthermore, due to the resilience of the imprinted material between the mold and the substrate, a force proportional to the moving amounts of the mold and the substrate required for alignment is applied to the mold, and deformation (distortion) of the mold thereby occurs.

### SUMMARY OF THE INVENTION

An object of the present invention is to provide an imprint apparatus capable of accurately adjusting the position of a mold.

One aspect of the imprint apparatus according to the present inventions is an imprint apparatus that forms a pattern of an imprint material on a substrate by using a mold comprising: at least one processor or circuit configured to function as a holding unit configured to hold the mold; and an actuator configured to apply a force to a side surface of the mold held by the holding unit; wherein the holding unit includes a first mechanism that is able to hold the mold and is capable of limiting a motion of the mold in a direction in which the actuator applies the force; wherein the holding unit includes a second mechanism, that is different from the first mechanism and that is able to hold the mold while allowing the motion of the mold in the direction in which the actuator applies the force.

Further features of the present invention will become apparent from the following description of embodiments with reference to the attached drawings.

### BRIEF DESCRIPTION OF THE DRAWINGS

FIG. 1 is a schematic diagram illustrating a configuration of an imprint apparatus according to an Embodiment of the present invention.

FIG. 2 is a schematic diagram of a mold holding unit of the imprint apparatus shown in FIG. 1 when viewed from below in the Z-axis direction.

FIG. 3 is a schematic diagram of the mold holding unit shown in FIG. 2 when viewed from below in the Z-axis direction when there is no mold.

FIG. 4 is a cross-sectional view of the mold holding unit shown in FIG. 2 in a predetermined operation.

FIG. 5 is a cross-sectional view of another operation of the mold holding unit shown in FIG. 2.

FIG. 6 is a flowchart for explaining an operation for adjusting the position of the mold.

FIG. 7 illustrates an example of a mechanism for maintaining an advantageous positional relationship between a vacuum suction port 102 and a mold holding unit 4.

### DESCRIPTION OF THE EMBODIMENTS

Hereinafter, with reference to the accompanying drawings, favorable modes of the present invention will be described using Embodiments. In each diagram, the same reference signs are applied to the same members or elements, and duplicate descriptions will be omitted or simplified.

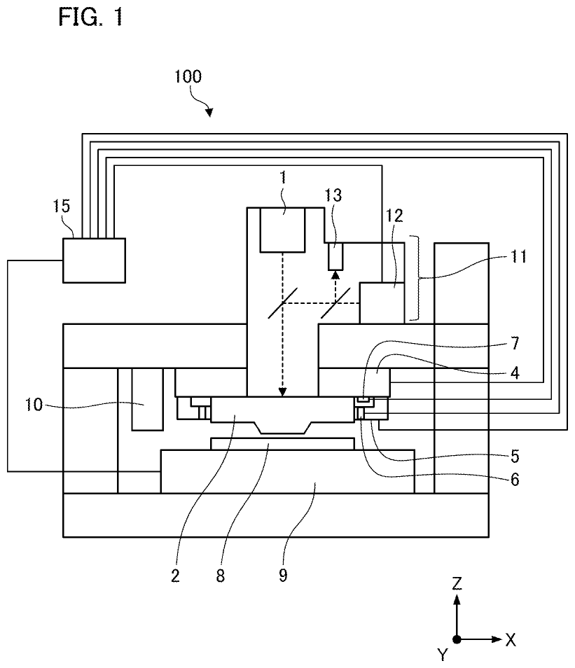

FIG. 1 is a schematic diagram illustrating a configuration of an imprint apparatus 100 according to an Embodiment of the present invention. The imprint apparatus 100 is a lithographic apparatus used in the manufacturing processing of a semiconductor device and performs an imprint process for forming a pattern of an imprint material on a substrate by using a mold. In the present Embodiment, the imprint apparatus 100 brings the imprint material supplied on the substrate into contact with the mold and applies energy for curing to the imprint material in order to form a pattern of the cured material to which an uneven pattern of the mold has been transferred.

As the imprint material, a curable composition (sometimes referred to as “uncured resin”) that is cured by applying energy for curing is used. Electromagnetic waves, heat, and the like are used as the energy for curing. As the electromagnetic waves, for example, light such as infrared rays, visible rays, and ultraviolet rays having a wavelength selected within a range between 10 nm or more and 1 mm or less are used.

The curable composition is a composition cured by light irradiation or by heating. The photocurable composition that is cured by light irradiation contains at least a polymerizable compound and a photopolymerization initiator and may contain a non-polymerizable compound or a solvent if necessary. The non-polymerizable compound is at least one type selected from the group including a sensitizer, a hydrogen donor, an internal mold release agent, a surfactant, an antioxidant, and a polymer component.

The imprint material may be applied in a film form on the substrate by a spin coater or a slit coater. The imprint material may be applied to the substrate by a liquid ejection head in the form of droplets or in the form of islands or films formed by connecting a plurality of droplets. The viscosity (viscosity at 25° C.) of the imprint material is, for example, equal to or greater than 1 mPa·s and less than or equal to 100 mPa·s.

As shown in FIG. 1, the imprint apparatus 100 has an irradiation unit 1, the mold holding unit 4, an actuator 5, a first measurement unit 6, a second measurement unit 7, a substrate stage 9, an imprint material supply unit 10, an alignment measurement unit 11, and a controller 15. The irradiation unit 1 irradiates the imprinted material on the substrate with ultraviolet rays through a mold 2. The irradiation unit 1 includes a light source and a plurality of optical elements for adjusting ultraviolet rays from the light source to a state suitable for imprinting processing.

The mold 2 has a rectangular outer shape when viewed from the Z-axis direction and is formed with a pattern having a three-dimensional shape (an uneven shape) to be transferred to the imprinted material on the substrate on a surface facing a substrate 8. The surface of the pattern of the mold 2 is processed with a high flatness for the purpose of maintaining adhesion with the imprinted material (substrate 8) on the substrate. The mold 2 is made of a material that transmits ultraviolet rays, for example, quartz.

The mold holding unit 4 includes a chuck and the like that attracts the mold 2 by a suction force and an electrostatic force and holds the mold 2. The mold holding unit 4 is driven by a mold driving unit. The mold driving unit drives the mold holding unit 4 in the Z-axis direction in order to bring the imprinted material on the substrate into contact with the mold 2 or to separate the mold 2 from the imprinted material on the substrate.

The actuator 5 (mold deformation mechanism) applies a force (compression force) to the side surface of the mold 2 held by the mold holding unit 4 to deform the pattern of the mold 2. The first measurement unit 6 includes a force sensor, for example, a load cell and a strain gauge, and measures a force applied to the side surface of the mold 2 from the actuator 5. A second measurement unit 7 includes a displacement sensor and measures the position of the side surface (displacement of the side surface) of the mold 2 held by the mold holding unit 4.

The imprint material supply unit 10 (dispenser) supplies (applies) an imprint material on the substrate. In the present Embodiment, the imprint material has the property of being cured by irradiation with ultraviolet rays (photo curability). The imprint material is appropriately selected depending on the type of semiconductor device to be manufactured. The substrate stage 9 holds the substrate 8 by vacuum suction and is freely movable in the X-Y plane.

The alignment measurement unit 11 includes a measurement light source 12, for example, a He—Ne laser, which emits light having a wavelength that does not cure the imprinted material on the substrate, and a detector 13, for example, a CCD image sensor. The alignment measurement unit 11 is used to perform alignment by superimposing the pattern of the mold 2 and the pattern (base) formed on the substrate 8. The alignment measurement unit 11 irradiates alignment marks formed in each of the mold 2 and the substrate 8 with light from the measurement light source 12 and detects an interference pattern formed by light from these marks using the detector 13 in order to measure the relative position of the marks.

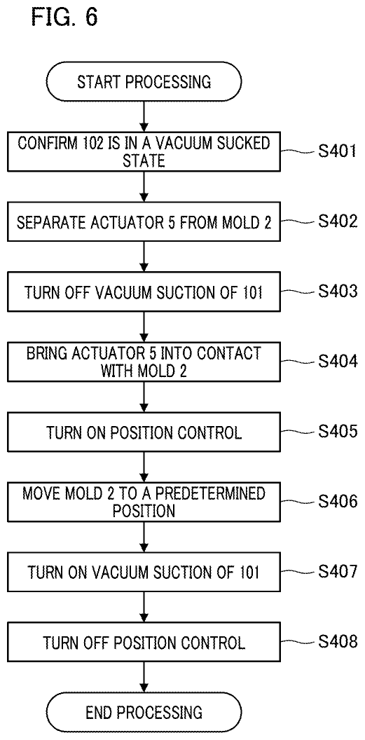

The controller 15 includes a CPU serving as a computer and a memory storing a computer program, controls the entire imprint apparatus 100 (operation) based on the computer program stored in the memory, and performs control of the mold, the imprint processing, and the like as shown in FIG. 6.

The controller 15 controls processing related to the alignment between the mold 2 and the substrate 8. For example, the misalignment between the mold 2 and the substrate 8 in each of the X-axis direction, the Y-axis direction, and the rotating direction is obtained based on the measurement results from the alignment measurement unit 11 (relative position of the alignment marks) and the misalignment between the mold 2 and the substrate 8 is corrected by moving the substrate stage 9.

Magnification between the mold 2 and the substrate 8, shape errors in skew, trapezoidal shape, arched shape, and bobbin winding are corrected by the actuator 5 deforming the pattern of the mold 2 to obtain a target shape. Open control and feedback control can be considered as the control for correcting the shape of the mold 2 by the actuator 5.

Examples of the open control include a control in which the mold 2 is deformed before it is brought into contact with the imprinted material on the substrate based on a shape correction amount obtained based on the result of the measurement of the pattern formed on the substrate 8 from a measuring device such as an SEM by the imprint processing. The feedback control is a control in which the mold 2 is deformed in real time based on the measurement result from the alignment measurement unit 11.

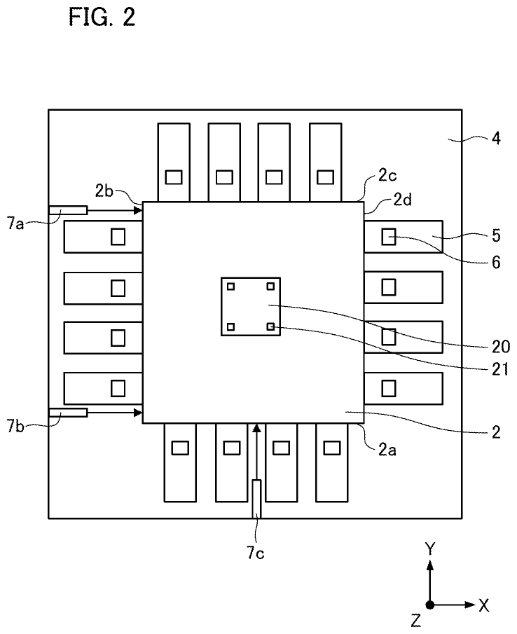

FIG. 2 is a schematic diagram of the mold holding unit of the imprint apparatus shown in FIG. 1 when viewed from below in the Z-axis direction, and illustrates an example of an arrangement of the mold 2, the actuator 5, the first measurement unit 6, and the second measurement unit 7 when viewed from below in the Z-axis direction. A pattern 20 to be transferred to the imprint material on the substrate is formed in the center of the mold 2. The pattern 20 includes alignment marks 21 for measuring the relative position to the alignment marks formed on the substrate 8.

With reference to FIG. 2, a plurality of actuators 5 is arranged to surround the mold 2, in other words, to face each of the four side surfaces 2a, 2b, 2c and 2d of the mold 2. In the present Embodiment, four actuators 5 are arranged on one side surface of the mold 2 (each of the side surfaces 2a to 2d). The actuators 5 are respectively supported by the mold holding unit 4 that holds the mold 2.

A piezo actuator having a small heating value and excellent responsiveness is typically used to serve as the actuator 5. The first measurement unit 6 that measures a force applied from the actuator 5 to the side surface of the mold 2 is disposed in each of the actuators 5.

The second measurement units 7 that measure the position of the side surface of the mold 2 are supported by the mold holding unit 4. At least three or more second measurement units 7 are arranged on two side surfaces orthogonal to each other from among four side faces 2a to 2d of the mold 2. In other words, the second measurement unit 7 includes at least three measuring axes for measuring the positions of two places on the side surface (first side surface) of the mold 2 and the position of one place on the side surface (second side surface) orthogonal to the first side surface.

The second measurement unit 7 functions as a position detecting means for detecting a misalignment amount from the target position of the mold 2 and can measure a misalignment X in the X-axis direction of the mold 2, the misalignment Y in the Y-axis direction of the mold 2, and the misalignment Qz in the rotating direction of the mold 2.

In the present Embodiment, as shown in FIG. 2, two second measuring units 7a and 7b are disposed on the side surface 2b of the mold 2 along the Y-axis direction and one second measurement unit 7c is disposed on the side surface 2a of the mold 2 along the X-axis direction. However, the present invention is not limited thereto.

For example, one second measurement unit 7 may be disposed on the side surface 2b of the mold 2, two second measurement units 7 may be disposed on the side surface 2a of the mold 2, or two second measurement units 7 may be disposed on each of the side surfaces 2a and 2b of the mold 2.

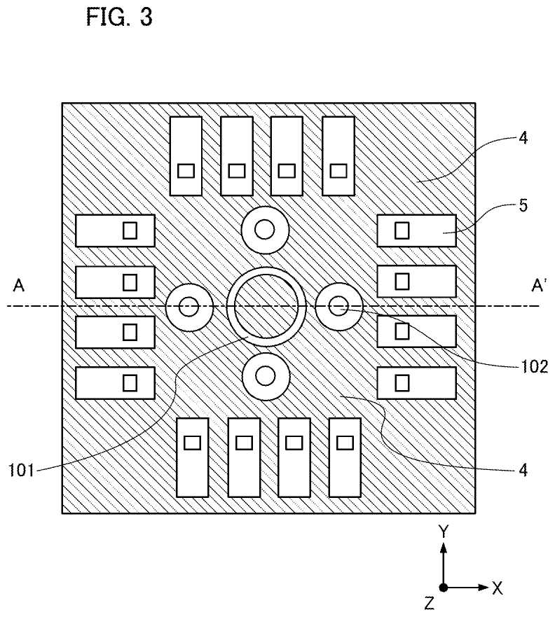

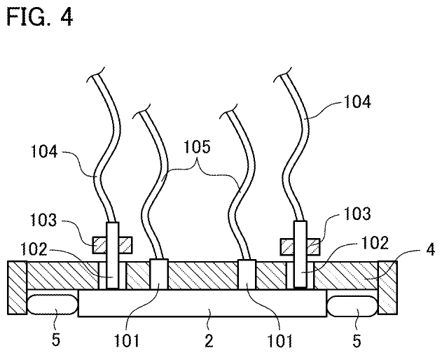

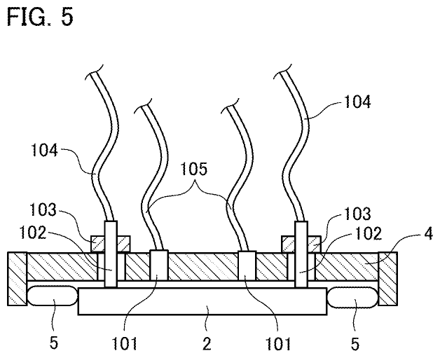

FIG. 3 is a schematic diagram of the mold holding unit shown in FIG. 2 when there is no mold as viewed from below in the Z-axis direction. In the mold holding unit 4, one or more vacuum suction ports 101 that are fixed to the mold holding unit and one or more vacuum suction ports 102 that are not directly fixed to the mold holding unit 4 are configured. FIG. 4 and FIG. 5 are cross-sectional views along the line A-A′ in FIG. 3, FIG. 4 is a cross-sectional view of a predetermined operation of the mold holding unit shown in FIG. 2, and FIG. 5 is a cross-sectional view of another operation of the mold holding unit shown in FIG. 2.

The vacuum suction port 101 has a structure in which there is a hole in the mold holding unit 4, by which a pipe 105 for connecting to a vacuum pump or the like is connected to the vacuum suction port 101, and a first suction unit is configured by the vacuum suction port 101, the pipe 105, the vacuum pump and the like. The first suction unit holds the mold 2 and configures a first mechanism that can limit the motion of the mold 2 in a direction in which the actuator 5 applies a force.

The vacuum suction port 102 is, for example, an iron pipe that is not directly fixed to the mold holding unit 4. A stopper 103 that limits downward motion by being brought into contact with the mold holding unit 4 is connected to the vacuum suction port 102, and a pipe 104 for connecting to a vacuum pump or the like is connected to the vacuum suction port 102. A second suction unit is configured by the vacuum suction port 102, the stopper 103, the pipe 104, the vacuum pump, and the like.

The second suction unit, which includes the vacuum suction port 102, the stopper 103 that is connected to the pipe, and the like, holds the mold 2 and configures a second mechanism that is different from the first mechanism, in which it is possible to allow the motion of the mold 2 in a direction in which the actuator 5 applies a force. The first mechanism and the second mechanism are not limited to configurations in which the mold 2 is sucked and held by a vacuum sucking force as described above and may be a mechanism in which the mold 2 is chucked and held, for example, by static electricity.

FIG. 4 illustrates an operation state in which the mold 2 is vacuum sucked by the vacuum suction port 101. At this time, attracting is performed so as to suck the mold 2 by the vacuum suction port 102 as well. This is to prevent the mold from dropping out of the vacuum suction port 101 when an abnormality occurs in the suction from the vacuum suction port 102. However, in this state, a distance between the lower surface of the stopper 103 and the leading end of the vacuum suction port 102 is set larger than the thickness of the mold holding unit 4 so that the stopper 103 does not come into contact with the mold holding unit 4.

Accordingly, the motion of the mold 2 is substantially restricted by only the vacuum suction port 101, and therefore it is possible to suppress changes in the mold shape as compared to a case in which the mold 2 is chucked at many points. The second mechanism does not interfere with the limitation of the motion of the mold 2 when the first mechanism limits the motion of the mold 2. That is, the second mechanism limits the motion of the mold 2 together with the first mechanism.

FIG. 5 illustrates an operation state in which the mold 2 is not vacuum sucked by the vacuum suction ports 101, or the suction force is substantially reduced and the mold 2 is vacuum sucked by only the vacuum suction port 102. At this time, the stopper 103 is brought into contact with the mold holding unit 4 and the mold 2 separates from the mold holding unit 4. In this state, the mold 2 can be easily displaced in the horizontal direction and the position of the mold 2 in the horizontal direction can be easily adjusted by applying the force of the actuator 5.

That is, when the motion of the mold 2 is not limited by the first mechanism, by having the stopper come into contact with the mold holding unit 4, the second mechanism limits the downward motion of the mold 2 dropping out, and permits motion in a direction in which the actuator 5 applies a force.

FIG. 6 is a flowchart for explaining an operation for adjusting the position of the mold. The flow of FIG. 6 is performed by the controller 15 reading a computer program from a memory and executing it.

With reference to FIG. 6, an adjustment operation for returning the misalignment of the mold 2 will be described. The mold 2 is in a vacuum sucked state by both the vacuum suction ports 101 and 102 except when misalignment is adjusted. Accordingly, even when an abnormality occurs in the suction operation of the vacuum suction port 101 as described above, the risk of the mold 2 dropping out of the mold holding unit 4 can be reduced.

In step S401, it is confirmed that the vacuum suction of mold 2 is being performed at the vacuum suction port 102 as a preparation for turning off the vacuum suction from the vacuum suction port 101, which limits the motion of mold 2 in all directions. This is because there is a risk that the mold 2 will drop out of the mold holding unit 4 if the vacuum suction from the vacuum suction port 101 is turned off when the vacuum suction of mold 2 is not being performed at the vacuum suction port 102.

If, in step S401, the vacuum suctioning of the mold 2 is not being performed properly at the vacuum suction port 102, the process in FIG. 6 stops until it is confirmed that the vacuum suctioning of the mold 2 is being performed properly at the vacuum suction port 102. Thus, the controller 15 includes an adjustment step of releasing the holding of the mold 2 by the first mechanism while the mold 2 is being held by the second mechanism and subsequently adjusting the position of the mold 2 by the actuator 5.

In step S402, the actuator 5 separates from the mold 2. This is so as to separate the mold 2 smoothly from the mold holding unit 4 when the process shifts from FIG. 4 to FIG. 5. Unless the actuator 5 prevents the mold 2 from separating from the holding portion 4, the actuator 5 may be in contact with the mold 2.

In step S403, the vacuum suction from the vacuum suction port 101 is turned off. As a result, the mold 2 is vacuum sucked only by the vacuum suction port 102 as shown in FIG. 5 and the mold 2 can be displaced in the horizontal direction.

In step S404, the actuator 5 is brought into contact with the mold 2. Accordingly, it is possible for the actuator 5 to move the mold 2. In step S405, position control for the mold 2 is turned on. The position control includes a position detecting step in which the relative position of the holding unit and the mold 2 is detected by the second measurement unit 7.

The control method also includes a control step in which the controller 15 drives the actuator 5 to perform control so that the deviation becomes 0 based on a detection result in the position detection step, that is, a signal indicating deviation from the target position, which is an output from the second measurement unit 7.

In step S406, the controller 15 sends an instruction for displacing the mold 2 in the predetermined horizontal direction to the actuator 5 in order to move the mold 2 to a predetermined target position. Thus, moving to the target position is performed. That is, when the motion of the mold 2 is not limited by the first mechanism, the controller 15 controls the driving of the actuator 5 based on the output of the second measurement unit 7 that serves as a position detecting means.

In step S407, the vacuum suction of the vacuum suction port 101 is turned on. Accordingly, the position of the mold 2 is fixed again. In step S408, the position control for the mold 2 is turned off. Specifically, the actuator is turned off. As described above, the controller 15 performs the holding by the first mechanism again and turns the actuator 5 off after the adjustment for the position for the mold 2 has been completed.

Next, an example will be given to describe a mechanism for maintaining an advantageous positional relation between the vacuum suction port 102 and the mold holding unit 4. If the positional relation between the vacuum suction port 102 and the mold holding unit 4 is disadvantageous, the motion of the mold 2 will be limited when the actuator 5 applies a force to the mold 2.

Accordingly, it is desirable that the vacuum suction port 102 returns to a neutral position at which a sufficient distance is ensured for the vacuum suction 102 to move in the direction where the actuator 5 applies a force to the mold 2 when the mold 2 is removed from the mold holding unit 4. That is, it is desirable that the vacuum suction port 102 is maintained at an appropriate position when the suction by the vacuum suction port 102 is turned off.

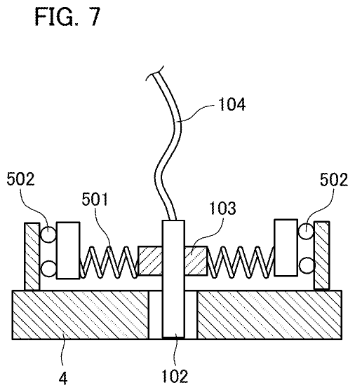

FIG. 7 illustrates an example of a mechanism for maintaining a predetermined positional relationship between the vacuum suction port 102 and the mold holding unit 4. The vacuum suction port 102 and the stopper 103 are supported by a spring 501 serving as an elastic or a resilient member and the spring 501 is supported at rolling bearings 502 from the mold holding unit 4. The spring 501 is configured to deform in the direction in which the actuator 5 applies a force. It is preferable that the spring constant is small so that an extra force is not applied to the mold 2.

However, if the spring constant is too small, the positional relationship between the mold holding unit 4 and the vacuum suction port 102 may not be maintained. The spring constant needs to be set within a degree in which the vacuum suction port 102 does not come into contact with the side surface of the hole of the mold holding unit 4 when the imprint apparatus is being operated. Thus, when the motion of the mold 2 is not limited by the first mechanism, the second mechanism is provided with, for example, an elastic member to serve as a return means for returning the vacuum suction port 102 to a predetermined position to the holding unit, and the adjustment of the mold can thereby be performed smoothly.

It is possible to perform the alignment of the mold with a high accuracy and to prevent the mold from dropping out by using the imprint apparatus according to the present Embodiment, as described above. Accordingly, productivity in manufacturing articles such as a micro device such as a semiconductor device and an element having a microstructure is improved.

A method for manufacturing a device (for example, a semiconductor device, a magnetic storage media, and a liquid crystal display device) serving as an article may include a step of forming a mold pattern on the surface of the substrate (for example, a wafer, glass plate, and film-like substrate) by using an imprint apparatus. The step of transferring the mold pattern may include a flattening step. The substrate is not limited to a single base material and may include a substrate having a multilayer structure.

The manufacturing method further includes a step of processing the substrate before or after the pattern forming step. For example, the processing step may include a step of removing a remaining film of the pattern and a developing step. The processing step may also include known steps such as a step of etching the substrate by using the pattern as a mask, a step of cutting out a chip from the substrate (dicing), a step of placing the chip on the frame and electrically connecting them (bonding), and a step of sealing with a resin (molding). The method for manufacturing an article by using the imprint apparatus according to the present embodiment is advantageous in at least one of the performance, quality, productivity, and production cost of the article as compared to the conventional methods.

While the present invention has been described with reference to exemplary embodiments, it is to be understood that the invention is not limited to the disclosed exemplary embodiments. The scope of the following claims is to be accorded the broadest interpretation to encompass all such modifications and equivalent structures and functions. In addition, as a part or the whole of the control according to this embodiment, a computer program realizing the function of the embodiment described above may be supplied to the imprint apparatus and so on through a network or various storage media. Then, a computer (or a CPU, an MPU, or the like) of the imprint apparatus and so on may be configured to read and execute the program. In such a case, the program and the storage medium storing the program configure the present invention.

This application claims the benefit of Japanese Patent Application No. 2021-003757 filed on Jan. 13, 2021, which is hereby incorporated by reference herein in its entirety.

What is claimed is:

1. An imprint apparatus that forms a pattern of an imprint material on a substrate by using a mold comprising:
at least one processor or circuit configured to function as
a holding unit configured to hold the mold; and
an actuator configured to apply a force to a side surface of the mold held by the holding unit;
wherein the holding unit includes a first mechanism that is able to hold the mold and is capable of limiting a motion of the mold in a direction in which the actuator applies the force; and
wherein the holding unit includes a second mechanism that is different from the first mechanism and that is able to hold the mold while allowing the motion of the mold in the direction in which the actuator applies the force.

2. The imprint apparatus according to claim 1,
wherein the second mechanism limits the motion of the mold together with the first mechanism when the motion of the mold is limited by the first mechanism.

3. The imprint apparatus according to claim 1,
wherein the second mechanism limits a motion of the mold in a direction in which the mold drops out and allows the motion of the mold in the direction in which the actuator applies the force when the motion of the mold is not limited by the first mechanism.

4. The imprint apparatus according to claim 1,
wherein the second mechanism has a return unit for returning to a predetermined position with respect to the holding unit when the motion of the mold is not limited by the first mechanism.

5. The imprint apparatus according to claim 2 further comprising:
a position detecting unit configured to detect a relative position between the holding unit and the mold; and
a controller configured to control the drive of the actuator based on the output of the position detecting unit when the motion of the mold is not limited by the first mechanism.

6. The imprint apparatus according to claim 5,
wherein the controller causes the first mechanism to release the mold while the mold is being held by the second mechanism and subsequently causes the actuator to adjust the position of the mold.

7. The imprint apparatus according to claim 6,
wherein the controller causes the first mechanism to hold the mold and to turn the actuator off after the adjustment of the position of the mold has been completed.

8. The imprint apparatus according to claim 1,
wherein the first mechanism and the second mechanism are mechanisms that chuck the mold by a vacuum sucking force or static electricity.

9. The imprint apparatus according to claim 1,
wherein the second mechanism has a pipe connected to a vacuum pump and a stopper connected to the pipe and limits the downward movement of the mold by having the stopper come into contact with the mold holding unit in a state in which the mold is sucked by a vacuum suction port at a leading end of the pipe.

10. A control method for controlling an imprint apparatus that forms a pattern of an imprint material on a substrate by using a mold, the imprint apparatus comprising:
a holding unit configured to hold the mold; and
an actuator configured to apply a force to a side surface of the mold held by the holding unit;
wherein the holding unit includes a first mechanism that is able to hold the mold and is capable of limiting a motion of the mold in a direction in which the actuator applies the force;
wherein the holding unit includes a second mechanism that is different from the first mechanism and that is able to hold the mold while allowing the motion of the mold in the direction in which the actuator applies the force,
the control method comprising:
detecting a relative position between the holding unit and the mold when the motion of the mold is not limited by the first mechanism; and
controlling the driving of the actuator based on a detection result in the detecting.

11. The control method according to claim 10,
wherein the controlling includes adjusting the position of the mold in a state in which the mold is held by the second mechanism by the actuator after the mold has been released by the first mechanism.

12. The control method according to claim 11,
wherein the controlling includes holding the mold by the first mechanism and turning the actuator off after the adjusting has been completed.

13. A non-transfer computer-readable storage medium configured to store a computer program for a control method of an imprint apparatus to execute the following steps:
controlling the imprint apparatus that forms a pattern of an imprint material on a substrate by using a mold,
the imprint apparatus comprising:
a holding unit configured to hold the mold; and
an actuator configured to apply a force to a side surface of the mold held by the holding unit;
wherein the holding unit includes a first mechanism that is able to hold the mold and is capable of limiting a motion of the mold in a direction in which the actuator applies the force;
wherein the holding unit includes a second mechanism that is different from the first mechanism and that is able to hold the mold while allowing the motion of the mold in the direction in which the actuator applies the force,
the control method comprising:
detecting a relative position between the holding unit and the mold when the motion of the mold is not limited by the first mechanism; and
controlling the driving of the actuator based on a detection result in the detecting.

14. A method of manufacturing an article by using an imprint apparatus that forms a pattern of an imprint material on a substrate by using a mold, the imprint apparatus comprising:
a holding unit configured to hold the mold; and
an actuator configured to apply a force to a side surface of the mold held by the holding unit;
wherein the holding unit includes a first mechanism that is able to hold the mold and is capable of limiting a motion of the mold in a direction in which the actuator applies the force;
wherein the holding unit includes a second mechanism that is different from the first mechanism and that is able to hold the mold while allowing the motion of the mold in a direction in which the actuator applies the force, the method comprising:
detecting a relative position between the holding unit and the mold when the motion of the mold is not limited by the first mechanism;
controlling the driving of the actuator based on a detection result in the detecting;
performing imprinting in which a pattern of an imprint material is formed on a substrate by using the imprint apparatus; and
manufacturing an article by using a substrate on which the pattern has been formed by performing the imprinting.
